(19) United States
(12) Patent Application Publication
(10) Pub. No.: US 2007/0196942 A1
(43) Pub. Date: Aug. 23, 2007

(54) Method for producing group III nitride crystal, group III nitride crystal obtained by such method, and group III nitride substrate using the same

(75) Inventors: Yasuo Kitaoka, Osaka (JP); Hisashi Minemoto, Osaka (JP); Isao Kidoguchi, Hyogo (JP); Takatomo Sasaki, Osaka (JP); Yusuke Mori, Osaka (JP); Fumio Kawamura, Osaka (JP)

Correspondence Address: HAMRE, SCHUMANN, MUELLER & LARSON P.C., P.O. BOX 2902-0902, MINNEAPOLIS, MN, 55402, US

(73) Assignee: Yusuke MORI, Osaka (JP)

(21) Appl. No.: 10/584,725

(22) PCT Filed: Dec. 22, 2004
(86) PCT No.: PCT/JP04/19249

§ 371 Date: Jun. 26, 2006

(30) Foreign Application Priority Data
Dec. 26, 2003 (JP) 2003-435072

(51) Int. Cl. H01L 21/00

(52) U.S. Cl. 438/46; 257/90

(57) ABSTRACT

In a nitrogen-containing atmosphere, a Group III nitride crystal is grown in a flux that includes at least one Group III element selected from Ga, Al, and In, an alkali metal, and Mg, thereby forming a Group III nitride substrate. Since Mg is a p-type dopant for the Group III nitride crystal, even if Mg is present in the crystal, the crystal can have p-type or semi-insulating electrical characteristics and causes no problem in its application to an electronic device. Moreover, the amount of nitrogen dissolved in the flux is increased because the flux includes Mg, which allows the crystal to be grown at a high growth rate and also improves the reproducibility of the crystal growth.

### TECHNICAL FIELD

The present invention relates to a method for producing a Group III nitride crystal, a Group III nitride crystal obtained by the method, and a Group III nitride substrate using the Group III nitride crystal.

### BACKGROUND ART

A Group III nitride compound semiconductor such as gallium nitride (GaN), which may be referred to as a “Group III nitride semiconductor” or “GaN semiconductor” in the following, has attracted attention as a material for a semiconductor device that emits blue or ultraviolet light. A blue laser diode (LD) is applied to a high-density optical disk or display, and a blue light-emitting diode (LED) is applied to a display or lighting. An ultraviolet LD is expected to be used in biotechnology, and an ultraviolet LED is expected to be used as an ultraviolet source of a fluorescent lamp.

A substrate of the Group III nitride semiconductor (e.g., GaN) for a LD or LED is formed generally by the heteroepitaxial growth of a Group III nitride crystal on a sapphire substrate with vapor phase epitaxy. Examples of the vapor phase epitaxy include metal organic chemical vapor deposition (MOCVD), hydrid vapor phase epitaxy (HVPE), and molecular beam epitaxy (MBE).

On the other hand, a method using liquid phase epitaxy instead of the vapor phase epitaxy also has been studied. The equilibrium vapor pressure of nitrogen at the melting point of the Group III nitride crystal such as GaN or AlN is 10,000 atm or more. Therefore, conventional liquid phase epitaxy of GaN has required the conditions of 8000 atm at 1200° C. In recent years, however, it has become clear that GaN can be synthesized at a relatively low temperature and pressure, i.e., 750° C. and 50 atm by using alkali metals (e.g., Na) as a flux.

For example, JP 2002-293696 A (Patent Document 1) discloses a method in which a mixture of Ga and Na is melted at 800° C. and 50 atm in a nitrogen gas atmosphere containing ammonia, and a crystal is grown from this melt (flux) for 96 hours. The crystal thus obtained has a maximum crystal size of about 1.2 mm.

Another method also has been reported in which a GaN crystal layer is deposited on a sapphire substrate by metal organic chemical vapor deposition (MOCVD), and then a crystal is grown by liquid phase epitaxy (LPE).

A GaN electronic device has potential for a high-frequency power device. A GaN semiconductor layer and an AlGaN semiconductor layer are formed on a sapphire substrate by MOCVD. Next, a source electrode, a gate electrode, and a drain electrode are formed on the AlGaN semiconductor layer. A two-dimensional electron gas concentration between the GaN semiconductor layer and the AlGaN semiconductor layer can be controlled by controlling the gate voltage, resulting in a high-speed transistor. Although the sapphire substrate is used at present, a GaN substrate capable of homoepitaxial growth will be needed in the future. As described in the conventional examples, when the vapor phase epitaxy such as MOCVD or HVPE is used for the heteroepitaxial growth of the Group III nitride crystal on the sapphire substrate, carrier control of the substrate is a problem. Also, when a Group III nitride crystal is produced by liquid phase epitaxy in which the Group III element reacts with nitrogen by using alkali metal as a flux, a nitrogen defect is likely to occur and the resultant substrate tends to be an n-type substrate, so that the electrical characteristics of the substrate are affected.

Patent Document 1: JP 2002-293696 A

### DISCLOSURE OF INVENTION

### Problem to be Solved by the Invention

It is an object of the present invention to provide a method for producing a Group III nitride crystal that has p-type or semi-insulating electrical characteristics and causes no problem in its application to an electronic device, a Group III nitride crystal obtained by the method, and a Group III nitride substrate using the Group III nitride crystal.

### MEANS FOR SOLVING PROBLEM

A method for producing a Group III nitride crystal of the present invention includes growing a crystal in a nitrogen-containing atmosphere by reacting at least one Group III element selected from Ga, Al, and In with nitrogen in a melt that includes a flux including an alkali metal. The flux further includes Mg.

A Group III nitride crystal of the present invention is produced by the production method of the present invention.

A Group III nitride crystal substrate of the present invention includes the Group III nitride crystal of the present invention.

### EFFECTS OF THE INVENTION

In the method for producing a Group III nitride crystal of the present invention, the flux includes not only an alkali metal but also Mg. Since Mg is a p-type dopant for the Group III nitride crystal, even if Mg is present in the crystal as an impurity, the crystal can have p-type or semi-insulating electrical characteristics and causes no problem in its application to an electronic device. Moreover, the amount of nitrogen dissolved in the melt is increased because the flux includes Mg, which allows the crystal to be grown at a high growth rate and also improves the reproducibility of the crystal growth. As will be described later, when the flux includes as a doping component at least one selected from an alkaline-earth metal (other than Mg) and Zn in addition to or instead of Mg, the crystal is doped with at least one of Mg, the alkaline-earth metal (other than Mg), and Zn during liquid phase epitaxy. Accordingly, the carrier control becomes easier and a nitrogen defect is suppressed, thus improving the insulating properties.

### BRIEF DESCRIPTION OF DRAWINGS

FIG. 1 is a schematic view showing an example of an apparatus for producing a Group III nitride substrate of the present invention.

FIG. 2 is a schematic view showing another example of an apparatus for producing a Group III nitride substrate of the present invention.

FIGS. 3A and 3B are graphs showing the amount of impurities in an example of a Group III nitride substrate of the present invention. FIG. 3A shows a background level and FIG. 3B shows the result of measurement of the substrate.

FIGS. 4A and 4B are graphs showing the amount of impurities in another example of a Group III nitride substrate of the present invention.

FIG. 4A shows a background level and FIG. 4B shows the result of measurement of the substrate.

FIG. 5 is a schematic cross-sectional view showing an example of a field-effect transistor using a Group III nitride substrate of the present invention.

FIG. 6 is a graph showing the result of evaluation by X-ray powder diffraction in an example of a Group III nitride crystal of the present invention.

FIG. 7 is a graph showing the relationship between the amount of Mg added and the amount of GaN deposited in an example of a Group III nitride crystal of the present invention.

FIG. 8 is a photograph showing an example of a Group III nitride crystal of the present invention.

FIG. 9 is a graph showing the result of photoluminescence evaluation in an example of a Group III nitride crystal of the present invention.

FIG. 10 is a graph showing the result of evaluation by X-ray diffraction in an example of a Group III nitride crystal of the present invention.

### DESCRIPTION OF REFERENCE NUMERALS

11 Source gas tank
12 Pressure regulator
13 Stainless steel container
14 Electric furnace
15 Crucible
51 GaN substrate
52 GaN layer
53 AlGaN layer
54 Source electrode
55 Gate electrode
56 Drain electrode
201 Growth chamber
202 Heater
203 Thermocouple
204 Crucible support
205 Rotation axis
206 Crucible
207 Melt (flux)
208 Seed substrate
209 Flow controller

### BEST MODE FOR CARRYING OUT THE INVENTION

In the production method of the present invention, it is preferable that Mg of the flux functions as at least one of a flux component and a doping component.

In the production method of the present invention, the flux may include as a doping component at least one selected from an alkaline-earth metal (other than Mg) and Zn in addition to or instead of Mg.

In the production method of the present invention, it is preferable that the nitrogen is supplied as a nitrogen-containing gas.

In the production method of the present invention, the alkaline-earth metal may include Ca, Be, Sr, and Ba. Among these elements, Ca is preferred.

In the production method of the present invention, it is preferable that the flux is a mixed flux of Na and Mg.

In the production method of the present invention, it is preferable that the proportion of Mg in the mixed flux is 0.001 to 10 mol %. With this range, a good crystal can be obtained. Mg of the mixed flux may function as a doping component. It is more preferable that the proportion of Mg is 0.01 to 3 mol %.

In the production method of the present invention, it is preferable that the Group III element is Ga and the Group III nitride is GaN.

In the Group III nitride crystal of the present invention, when Mg is used as a doping component, the doping amount of Mg may be more than 0 and not more than 1×10²⁰ cm⁻³. When the Group III nitride crystal is formed as a p-type substrate, the doping amount of Mg may be 1×10¹⁸ to 1×10²⁰ cm⁻³.

In the Group III nitride crystal of the present invention, the total doping amount of Mg, the alkaline-earth metal (other than Mg), and Zn is preferably more than 0 and not more than 1×10¹⁷ cm⁻³, and more preferably 1×10¹⁶ to 1×10¹⁷ cm⁻³. The total doping amount means the sum of all the doping amounts of Mg, the alkaline-earth metal (other than Mg), and Zn.

Although the oxygen concentration of the Group III nitride crystal should be 0 cm⁻³, it may be 0 to 1×10¹⁷ cm⁻³, and preferably 0 to 1×10¹⁶ cm⁻³.

The resistivity (specific resistance) of the Group III nitride crystal is preferably not less than 1×10³ Ω·cm, and more preferably not less than 1×10⁵ Ω·cm.

The Group III nitride substrate may be a p-type substrate or a semi-insulating substrate.

Next, an example of the production method of the present invention will be described. In this method, a Group III nitride substrate is produced by growing a Group III nitride crystal on a seed layer (seed crystal) of a seed crystal substrate.

The crystal growth apparatus includes a growth chamber. It is preferable that at least the inner surface of the growth chamber is made of a material that does not include Si. For example, the growth chamber may be formed of stainless steel. A crucible is placed inside the growth chamber. It is preferable that the crucible also is made of a material that does not include Si. For example, the crucible may be formed of boron nitride (BN), alumina (Al₂O₃), magnesia (MgO), or calcia (CaO). A pipe is connected to the growth chamber for supplying a source gas. The pipe does not include Si and may be formed of metal. Examples of the metal include a stainless steel (SUS) material and copper.

First, a Group III element and an alkali metal are placed in the crucible and melted to form a melt (flux) by heating the crucible under pressure. The Group III element is selected in accordance with a semiconductor to be grown from the melt and may be Ga, Al, or In. These elements can be used either individually or in combinations of two or more. Only Ga is used to form a GaN crystal. The alkali metal may be Na, Li, or K. These elements also can be used either individually or in combination of two or more. The alkali metal generally functions as a flux (the same is true for the following embodiments). In particular, Na is preferred. When Na is used, it should be purified to 99.99%. The purification of Na may be performed by heating and melting Na in a glove box where the gas is replaced by He (or any of N₂, Ar, Ne, and Xe) and removing an oxide or the like that appears on the surface layer. Alternatively, zone refining may be used to purify Na. In the zone refining, impurities are precipitated while Na is melted and solidified repeatedly in a tube, and then the impurities are removed to increase the purity of Na. In the present invention, the melt (flux) includes Mg.

Then, a Group III nitride crystal is grown on the seed crystal of the substrate. For example, the substrate may include a base substrate and a nitride seed crystal formed on at least one side of the base substrate or may consist of a nitride crystal. The base substrate may be a sapphire substrate, GaAs substrate, Si substrate, SiC substrate, or AlN substrate. The substrate also may have an ELOG structure (the same is true for the following embodiments). The seed crystal may be a Group III nitride crystal.

The Group III nitride crystal used as the seed crystal can be formed, e.g., by metal organic chemical vapor deposition (MOCVD), molecular beam epitaxy (MBE), or hydrid vapor phase epitaxy (HVPE).

The Group III nitride crystal is grown on the seed crystal by the reaction of the Group III element with nitrogen. This crystal growth can produce a Group III nitride crystal (e.g., GaN crystal) expressed as a composition formula: AlₓGa_{y}In_{1-x-y}N (where 0≦x≦1, 0≦y≦1, and x+y≦1).

The Group III nitride crystal can be produced, e.g., by bringing one principle surface (i.e., the surface on which the seed crystal is formed) of the substrate into contact with the melt (flux), and then controlling the temperature of the melt (flux) and the pressure of the growth chamber so that a crystal of the Group III nitride semiconductor is grown as a result of supersaturation. In this case, Mg of the melt (flux) may function as at least one of a flux component and a doping component. It is preferable to use a mixed flux of Na and Mg. The proportion of Mg in the mixed flux has been described above.

During the crystal growth, it is preferable that the atmosphere in the growth chamber is maintained under a pressure of more than 1 atm and not more than 50 atm. Although the conditions of melting the materials and growing the crystal vary depending on the component of the flux or the component and pressure of the atmospheric gas, e.g., the temperature is 700 to 1100° C. and the pressure is about 1 to 100 atm. The growth process is performed preferably at a low temperature of 700 to 900° C.

The above production method can provide a p-type or semi-insulating Group III nitride crystal. The portion (the sapphire substrate) other than the Group III nitride crystal is removed, e.g., by grinding after the crystal has been grown, resulting in a substrate that consists of the Group III nitride crystal.

In the production method, it is preferable to control the oxygen concentration. The substrate doped with oxygen can be an n-type substrate, and therefore the oxygen concentration needs to be reduced. The preferred range of the oxygen concentration has been described above.

With the production method, the p-type or semi-insulating Group III nitride crystal can be produced easily compared to a conventional technique such as vapor phase epitaxy. Thus, a p-type or semi-insulating Group III nitride substrate with high characteristics can be produced at low cost.

As described above, the flux may include as a doping component at least one selected from the alkaline-earth metal (e.g., Ca, Be, Sr, or Ba) and Zn in addition to or instead of Mg. These elements can be used either individually or in combinations of two or more. Thus, at least one selected from Mg, the alkaline-earth metal (other than Mg), and Zn of the melt (flux) is incorporated into the Group III nitride crystal as a doping component. In particular, Ca is used preferably in an amount of 0.001 to 5 mol %, and more preferably 0.01 to 0.1 mol %. The total amount of Mg, the alkaline-earth metal (other than Mg), and Zn is preferably 0.001 to 0.1 mol %, apart from the case where Mg functions not only as a doping component but also as a flux component.

In this manner, a semi-insulating Group III nitride crystal doped with at least one selected from Mg, the alkaline-earth metal (other than Mg), and Zn can be produced. The portion (the sapphire substrate) other than the Group III nitride crystal is removed, e.g., by grinding after the crystal has been grown, resulting in a substrate that consists of the Group III nitride crystal. Consequently, the Group III nitride substrate is doped with at least one selected from Mg, the alkaline-earth metal (other than Mg), and Zn. The total doping amount of Mg, the alkaline-earth metal (other than Mg), and Zn has been described above.

A mechanism for improving the insulating properties by doping with at least one selected from Mg, the alkaline-earth metal (other than Mg), and Zn will be described below. The doping effects of at least one selected from Mg, the alkaline-earth metal (other than Mg), and Zn are considered as follows: 1) suppressing the occurrence of a Ga defect; 2) compensating for the carrier generation due to a nitrogen defect. Therefore, while a Group III nitride substrate produced by a general method acts as an n-type substrate, the substrate doped with at least one selected from Mg, the alkaline-earth metal (other than Mg), and Zn exhibits high insulating properties. Since the acceptor level of Zn is likely to be deeper than that of Mg and the alkaline-earth metal (other than Mg), Zn can make the insulating properties even higher.

In the above production method, the Group III nitride crystal with controlled insulating properties can be produced easily compared to a conventional technique such as vapor phase epitaxy. Thus, a semi-insulating Group III nitride substrate with high characteristics can be produced at low cost.

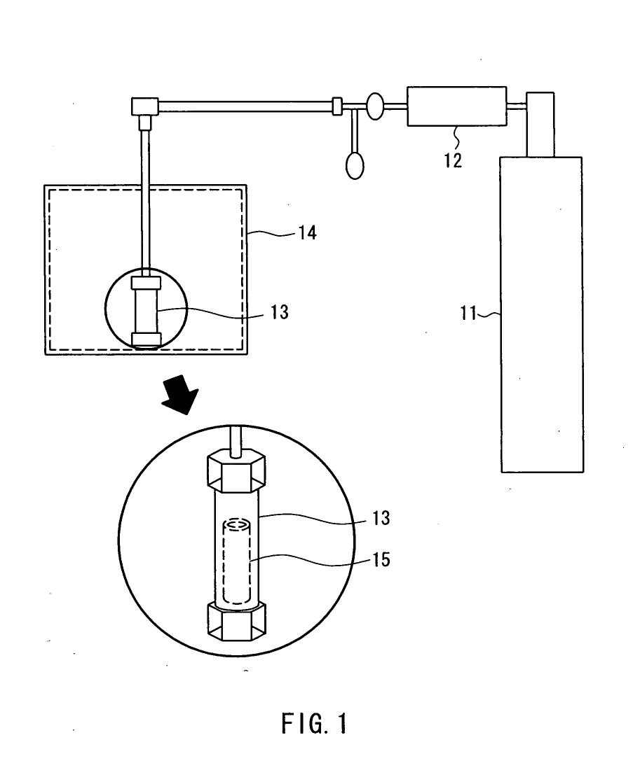

FIG. 1 shows an example of an apparatus used for the production method of the present invention. As shown in FIG. 1, the growth apparatus includes a source gas tank 11 for supplying a nitrogen gas (source gas), a pressure regulator 12 for regulating the pressure of a growth atmosphere, a stainless steel container 13 for crystal growth, and an electric furnace 14. A crucible 15 made of, e.g., alumina (Al₂O₃) is set in the stainless steel container 13. The temperature of the electric furnace 14 can be controlled to 600 to 1000° C. The ambient pressure can be controlled to 100 atm or less by the pressure regulator 12.

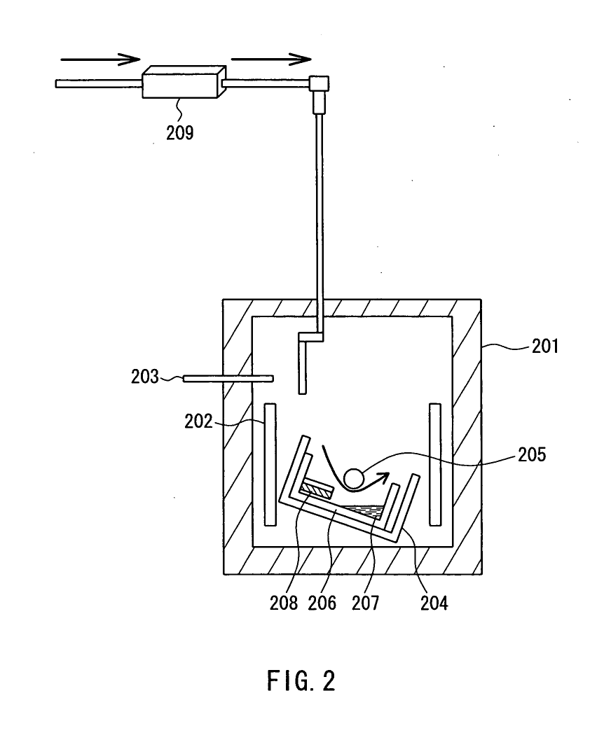

FIG. 2 shows another example of an apparatus used for the production method of the present invention. This apparatus is used for producing a large Group III nitride crystal. As shown in FIG. 2, the growth apparatus includes a stainless steel growth chamber 201 and is designed to withstand 50 atm. The growth chamber 201 includes a heater 202 and a thermocouple 203. A crucible support 204 is placed in the growth chamber 201 and has a mechanism for rotating around a rotation axis 205. A crucible 206 made of, e.g., alumina (Al₂O₃) is fixed in the crucible support 204. A melt (flux) 207 and a seed substrate 208 are arranged in the crucible 206. When the crucible support 204 rotates, the melt (flux) 207 in the crucible 206 moves repeatedly from side to side, and thus can be stirred. The flow controller 209 controls the ambient pressure. As a source gas, a nitrogen gas or a mixed gas of an ammonia gas (NH₃ gas) and a nitrogen gas is supplied from the source gas tank 11, and a gas purifier that is located upstream of the flow controller 209 removes impurities from the source gas. Subsequently, the purified gas is transferred into the growth chamber 201. An example of crystal growth using this growth apparatus will be described below.

(1) First, a Group III element, an alkali metal, and Mg are weighed out in a predetermined amount and placed in the crucible 206. The alkali metal and Mg are used as a flux. At the same time, the seed substrate 208 is fixed. As described above, the flux also may include as a doping component at least one selected from the alkaline-earth metal (other than Mg) and Zn in addition to or instead of Mg.

(2) After sealing the growth chamber 201, evacuation and nitrogen substitution are performed two or more times to remove oxygen or moisture in the atmosphere. The growth chamber 201 is filled with nitrogen, and the materials in the crucible 206 are melted by heating them under pressure. In this stage, the seed substrate 208 is not brought into contact with the melt (flux) 207, as shown in FIG. 2. The melt (flux) 207 is mixed while the crucible 206 is rocked sufficiently so that the melt (flux) 207 does not adhere to the seed substrate 208.

(3) Then, the crucible 206 is rotated around the rotation axis 205, and the seed substrate 208 is put into the melt (flux) 207. Thus, crystal growth starts.

(4) During the crystal growth, the crucible 206 swings at a speed of one period per minute so that the melt (flux) 207 is stirred with the seed substrate 208 remaining present in the melt (flux) 207. The LPE growth is performed for a predetermined time while maintaining the temperature and pressure of the crucible 206.

(5) After the crystal growth is finished, the crucible 206 is rotated as shown in FIG. 2, and the substrate is taken out of the melt (flux) 207, followed by reducing the temperature of the melt (flux) 207.

Next, a method for manufacturing an electronic device using the Group III nitride substrate of the present invention will be described by taking a field-effect transistor as an example.

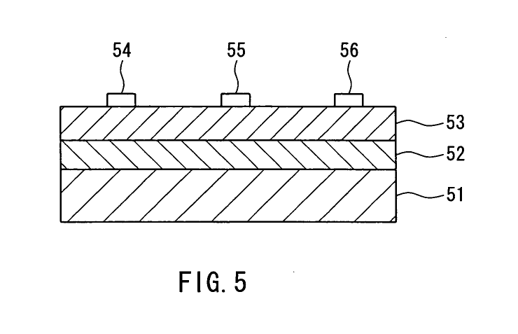

FIG. 5 schematically shows an example of the structure of the field-effect transistor. A Group III nitride substrate 51 of the present invention is produced by liquid phase epitaxy. A GaN layer 52 and an AlGaN layer 53 are formed on the Group III nitride substrate 51 by MOCVD. Moreover, a source electrode 54, a Schottky gate electrode 55, and a drain electrode 56 are formed on the AlGaN layer 53. A two-dimensional electron gas concentration in the interface between the GaN layer 52 and the AlGaN layer 53 is controlled by applying a voltage to the gate electrode 55, so that the device operates as a transistor.

The Group III nitride substrate of the present invention is, e.g., a p-type substrate or a semi-insulating substrate. Therefore, the field-effect transistor using this substrate is superior in high-frequency properties. Moreover, the Group III nitride substrate doped with at least one selected from Mg, the alkaline-earth metal (other than Mg), and Zn has the advantages of high resistance, few defects, and a small dislocation density, and thus can improve the insulating properties. Accordingly, the field-effect transistor using this substrate can reduce a leakage current during operation.

### EXAMPLES

### Example 1

Using the growth apparatus of FIG. 1, a crystal growth process was performed with a mixed flux of Na and Mg. In a glove box where the gas was replaced by Ar, materials of Ga, Na, and Mg were weighed out in a predetermined amount and placed in the crucible 15. The crucible 15 was made of yttria (Y₂O₃). Ga had a purity of 99.9999% (“six-nines”), and Na was purified to 99.99%. In this example, the resultant crystal was evaluated by changing the proportion of Mg in the mixed flux, while 2 g of Ga and 2.2 g of Na were weighed out.

The crucible 15 was inserted in the stainless steel container 13. Then, the stainless steel container 13 was sealed and set in the electric furnace 14, to which the pipe was connected. The ambient pressure and the growth temperature were controlled by the pressure regulator 12 and the electric furnace 14. In this example, the growth temperature was 850° C. and the nitrogen ambient pressure was 25 atm. The temperature was raised from room temperature to the growth temperature over the course of 1 hour, retained at the growth temperature for 96 hours, and reduced to room temperature over the course of 1 hour.

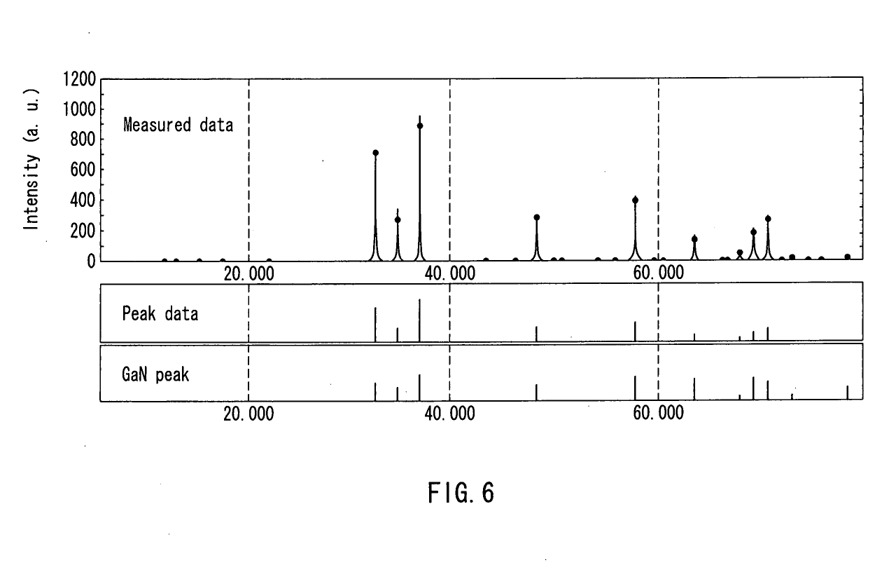

After this crystal growth process, a crystal was deposited on the sidewall of the crucible 15. The crystal was evaluated by X-ray powder diffraction. The graph of FIG. 6 shows the results. As shown in FIG. 6, the evaluation confirmed that the deposited crystal was a GaN crystal.

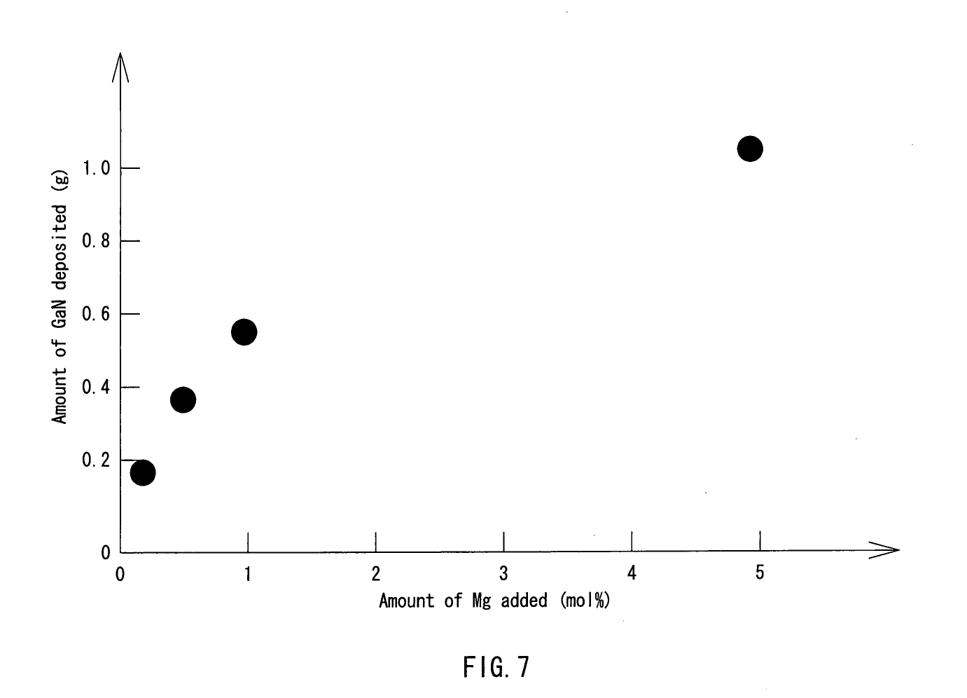

The mass (g) of the GaN crystal was evaluated when the proportion of Mg was changed. The graph of FIG. 7 shows the results. As shown in FIG. 7, 0.15 g of GaN crystal was deposited for 0.1 mol % of Mg. The amount of the GaN crystal deposited was increased with an increase in the proportion of Mg. Thus, the evaluation confirmed that the addition of Mg increased the amount of nitrogen dissolved in the flux and accelerated the growth of the GaN crystal.

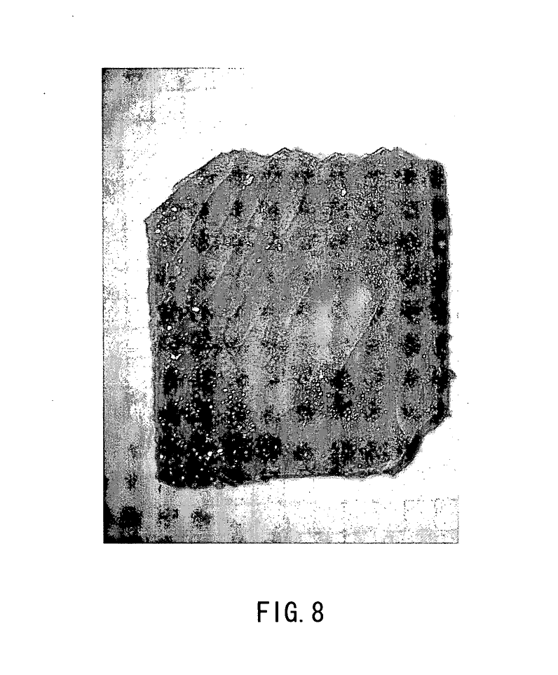

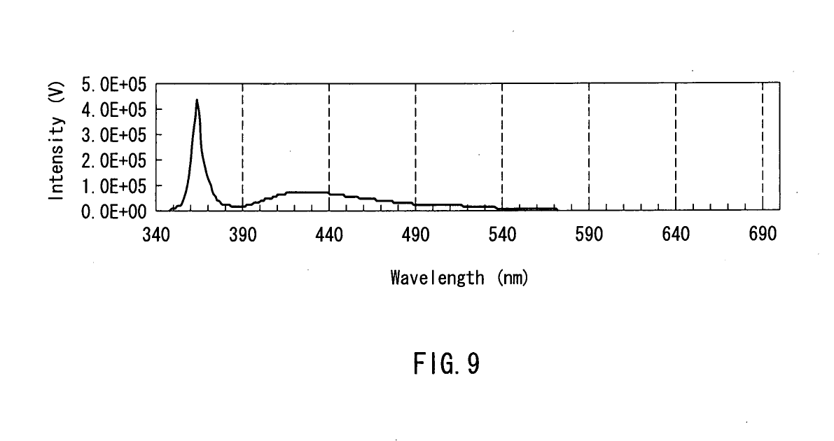

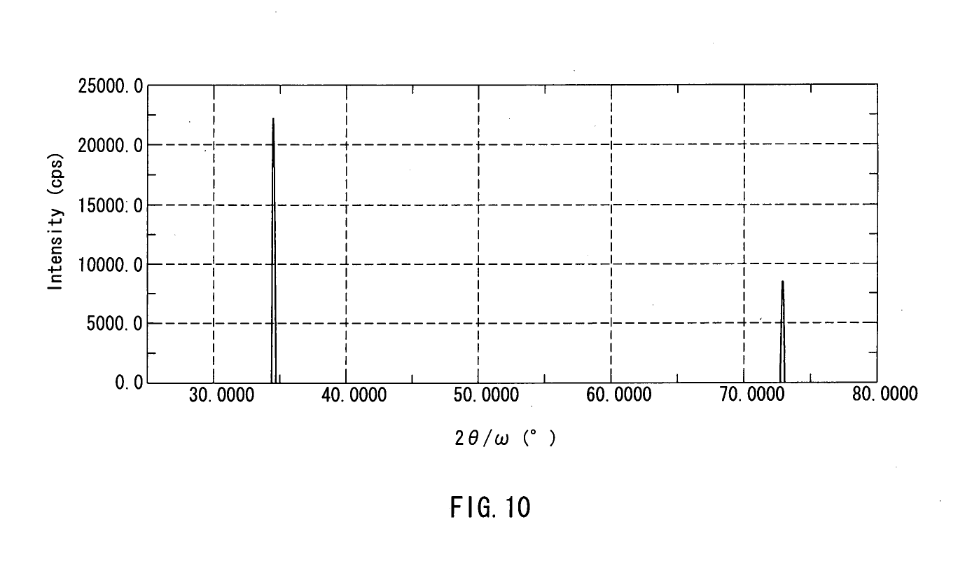

Next, a seed substrate was put in the crucible 15, and a liquid phase epitaxy experiment was conducted. As the seed substrate, a 10 μm thick GaN crystal was formed on a sapphire substrate by MOCVD. FIG. 8 is a picture of a GaN crystal obtained when the proportion of Mg was 0.5 mol %. As shown in FIG. 8, the GaN crystal was transparent. The photoluminescence of the GaN crystal was evaluated by using a HeCd laser (325 nm) as a light source. The graph of FIG. 9 shows the results. As shown in FIG. 9, the band edge emission was observed at 363 nm and its half-width was 6.7 nm. The blue band or yellow band emission due to impurities or the like was small, and therefore the GaN crystal had high quality. Moreover, the GaN crystal was evaluated by double crystal X-ray diffraction to measure a rocking curve. Specifically, X-rays emitted from an X-ray source were made highly monochromatic through a first crystal and then illuminated a second crystal (sample), thereby determining a FWHM (full width at half maximum) with its center at a peak of the X-rays diffracted from the sample. The graph of FIG. 10 shows the results. As shown in FIG. 10, the peak was detected only in the C-axis direction of the GaN crystal by ω/2θ scanning (rotation of both the crystal and the detector). This indicates the formation of a thick crystal. Although not shown in FIG. 10, ω scanning (rotation of only the crystal) evaluation confirmed that the half-width of the rocking curve was 100 sec, and the insulating properties were good. The X-ray source is not particularly limited, and may be, e.g., a CuK alpha-ray source. The first crystal also is not particularly limited, and may be, e.g., a InP crystal or Ge crystal.

### Example 2

Using the growth apparatus of FIG. 1, a GaN substrate doped with Ca was produced. In a glove box where the gas was replaced by nitrogen, materials of Ga and Na (flux) were weighed out in a predetermined amount and placed in the crucible 15. Na and Ga had the same purities as those in Example 1, respectively. In this example, 1 g of Ga and 0.88 g of Na (molar ratio (Ga/(Ga+Na))=0.27) were weighed out. Moreover, 0.001 g of Ca (0.065 mol % with respect to Na) was weighed out as a doping component and put in the crucible 15.

The crucible 15 was inserted in the stainless steel container 13. Then, the stainless steel container 13 was sealed and set in the electric furnace 14, to which the pipe was connected. The ambient pressure and the growth temperature were controlled by the pressure regulator 12 and the electric furnace 14. In this example, the growth temperature was 850° C. and the nitrogen ambient pressure was 30 atm. The temperature was raised from room temperature to the growth temperature over the course of 1 hour, retained at the growth temperature for 48 hours, and reduced to room temperature over the course of 1 hour.

The Ca-doped GaN substrate thus obtained was evaluated. The resistance of the substrate was measured with a tester, and the substrate had the insulating properties as high as 100 MΩ or more. Detailed measurement of the substrate with a four-terminal method or the like showed that the resistivity (specific resistance) was 5×10⁴ Ω·cm.

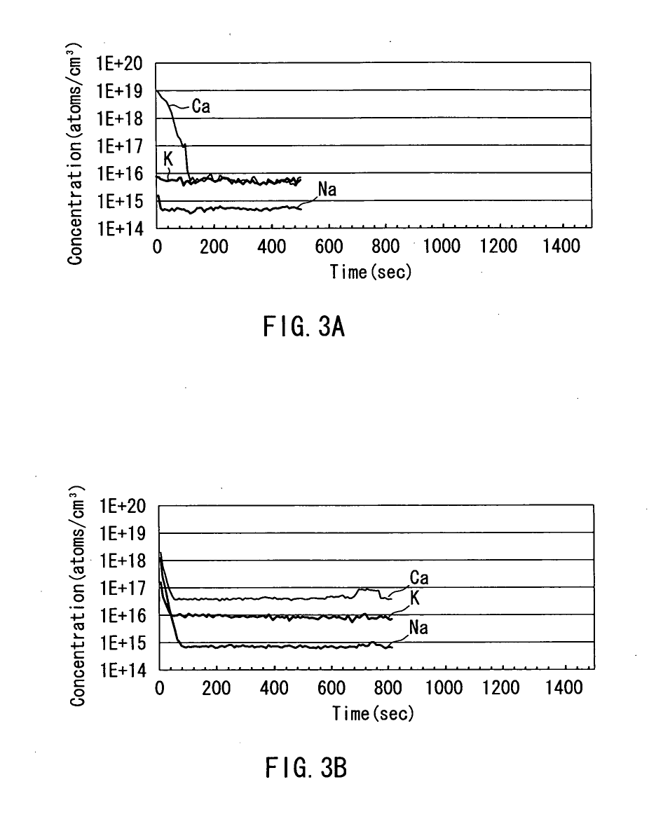

Next, the amount of impurities in the GaN substrate was evaluated by SIMS (secondary ion mass spectroscopy). The graphs of FIG. 3 show the results. FIG. 3A shows a background level. The vertical axis represents the count number of atoms. The horizontal axis represents time from which the depth from the substrate surface can be derived. Oxygen was used as an accelerated electron. It is clear from FIGS. 3A and 3B that Na and K were approximately the same as the background level and thus not present in the GaN substrate. The background level of Ca was about 0.01 ppm in FIG. 3A. The doping amount of Ca was estimated based on FIGS. 3A and 3B. Consequently, the substrate was doped with about 0.05 ppm of Ca. Here, 1 ppm measured by SIMS corresponds to about 1×10¹⁷ cm⁻³. Therefore, the doping amount of Ca expressed as 0.05 ppm was a value on the order of 1015.

### Example 3

Using the growth chamber of FIG. 2, a GaN substrate doped with Mg was produced. As a seed substrate, a 10 μm thick and 20 mm square GaN crystal was formed on a sapphire substrate by MOCVD. In this example, 5 g of Na, 5 g of Ga, and 0.003 g of Mg (0.06 mol % with respect to Na) were weighed out and put in the crucible. Na and Ga had the same purities as those in Example 1, respectively. While the growth chamber was maintained at 870° C. and 50 atm, LPE growth was performed for 50 hours. Then, a crystal started to grow from the GaN film of the seed substrate, resulting in a 500 μm thick and 20 mm square GaN crystal. In the GaN crystal thus obtained, the sapphire substrate of the seed substrate was removed to provide a self-supported GaN substrate.

The electrical characteristics of the Mg-doped self-supported GaN substrate were evaluated. The resistance of the substrate was measured with a tester, and the substrate had the insulating properties as high as 100 MΩ or more. Detailed measurement of the substrate with a four-terminal method or the like showed that the resistivity (specific resistance) was 5×10³ Ω·cm. On the other hand, when the electrical characteristics of a crystal grown from the melt (flux) that was not doped with Ca or Mg, but included only Na and Ga were evaluated, the resistance was 100 kΩ or less.

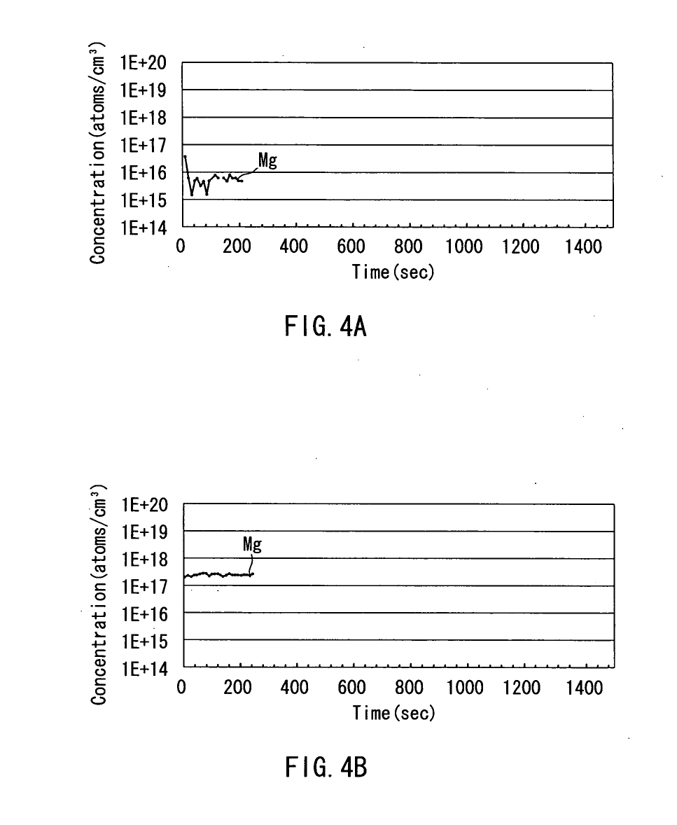

Next, the amount of impurities in the self-supported GaN substrate was evaluated by SIMS (secondary ion mass spectroscopy). The graph of FIG. 4 shows the results. FIG. 4A shows a background level. The vertical axis represents the count number of atoms. The horizontal axis represents time from which the depth from the substrate surface can be derived. Oxygen was used as an accelerated electron. The background level of Mg was about 0.01 ppm in FIG. 4A. The doping amount of Mg was estimated based on FIGS. 4A and 4B. Consequently, the substrate was doped with about 0.1 ppm of Mg. Here, 1 ppm measured by SIMS corresponds to about 1×10¹⁷ cm⁻³. Therefore, the doping amount of Mg expressed as 0.1 ppm was a value on the order of 10¹⁶.

The evaluation of the impurities in the depth direction of the seed substrate from which the GaN crystal was grown revealed the following. The surface of the seed substrate was melted back, and a highly defective layer was formed thereon. The highly defective layer had a large dislocation density and also included many impurities such as a flux. Moreover, a high-quality and high-resistance substrate whose cation site was doped with the alkaline-earth metal was formed on the highly defective layer. This substrate had a small dislocation density.

In this example, the Mg-doped GaN substrate had a resistivity (specific resistance) of 5×10³ Ω·cm. By increasing the doping amount of Mg to 0.5 ppm (5×10¹⁶ cm⁻³), the resistivity further was increased to 5×10^{5 Ω·cm.}

As is evident from Examples 2 and 3, when the melt (flux) of Na and Ga includes an alkaline-earth metal in an amount of 0.1 mol % or less with respect to Na, the crystal can be doped with about 0.1 to 1 ppm of the alkaline-earth metal. Thus, it is possible to improve the insulating properties of the GaN crystal.

### Example 4

A GaN substrate doped with Zn was produced in the same manner as Example 3 except that 0.005 g of Zn (0.035 mol % with respect to Na) was used as a doping component. The resistivity (specific resistance) of the resultant substrate was 5×10⁵ Ω·cm in.

A nitride substrate produced by liquid phase epitaxy using an alkali metal (e.g., Na) as a flux is likely to have a low resistivity (specific resistance) due to the influence of a nitrogen defect or the like. In contrast, Examples 2 to 4 proved for the first time that the GaN substrate produced by liquid phase epitaxy can be doped with Mg, Ca, or Zn, and thus can provide a semi-insulating substrate with a high resistivity (specific resistance).

Although the GaN substrates of Examples 2 to 4 were doped with Ca, Mg, and Zn, doping with other doping components also can be performed in the same manner.

In Examples 2 to 4, the GaN substrate was described as a semi-insulating Group III nitride substrate. However, a Group III nitride substrate such as AlN or AlGaN, expressed as a composition formula: AlₓGa_{y}In_{1-x-y}N (where 0≦u≦1, 0≦v≦1, and u+v≦1), can be expected to provide a similar effect. For example, a AlN crystal can be grown by using Li as a flux and dissolving nitrogen in the melt (flux) of Al and Li. In this case, the AlN crystal also can be doped with at least one selected from Mg, an alkaline-earth metal (other than Mg), and Zn, thereby producing a semi-insulating AlN substrate.

### INDUSTRIAL APPLICABILITY

A p-type or semi-insulating Group III nitride substrate of the present invention is applicable, e.g., to an electronic device such as a field-effect transistor, and particularly to a high-frequency power device.

1. A method for producing a Group III nitride crystal comprising:
growing a crystal in a nitrogen-containing atmosphere by reacting at least one Group III element selected from Ga, Al, and In with nitrogen in a melt that includes a flux including an alkali metal,
wherein the flux further includes Mg.

2. The method according to claim 1, wherein Mg of the flux functions as at least one of a flux component and a doping component.

3. The method according to claim 1, wherein the flux includes as a doping component at least one selected from an alkaline-earth metal and Zn.

4. The method according to claim 1, wherein the nitrogen is supplied as a nitrogen-containing gas.

5. The method according to claim 3, wherein the alkaline-earth metal is at least one selected from Ca, Be, Sr, and Ba.

6. The method according to claim 1, wherein the flux is a mixed flux of Na and Mg.

7. The method according to claim 6, wherein a proportion of Mg in the mixed flux is 0.001 to 10 mol %.

8. The method according to claim 6, wherein the Group III element is Ga and the Group III nitride is GaN.

9. A Group III nitride crystal produced by the method according to claim 1.

10. The Group III nitride crystal according to claim 9, wherein a doping amount of Mg is more than 0 and not more than 1×10²⁰ cm⁻³.

11. The Group III nitride crystal according to claim 9, wherein the Group III nitride crystal includes at least one selected from an alkaline-earth metal and Zn, and a total doping amount of Mg, the alkaline-earth metal (other than Mg), and Zn is more than 0 and not more than 1×10¹⁷ cm⁻³.

12. The Group III nitride crystal according to claim 9, wherein an oxygen concentration of the crystal is 0 to 1×10¹⁷ cm⁻³.

13. The Group III nitride crystal according to claim 9, wherein a resistivity (specific resistance) is not less than 1×10³ Ω·cm.

14. The Group III nitride crystal according to claim 9, wherein a resistivity (specific resistance) is not less than 1×10⁵ Ω·cm.

15. A Group III nitride substrate comprising the Group III nitride crystal according to claim 9.

16. The Group III nitride substrate according to claim 15, wherein the substrate is a p-type substrate or a semi-insulating substrate.

17. A field-effect transistor comprising the Group III nitride substrate according to claim 16.
